(19) United States
(12) Patent Application Publication
(10) Pub. No.: US 2025/0342900 A1
(43) Pub. Date: Nov. 6, 2025

(54) VIRTUAL BLOCK MULTI-PLAN ACCESS SYSTEM

(71) Applicant: Micron Technology, Inc., Boise, ID (US)

(72) Inventors: Guang Hu, Mountain View, CA (US); Devin Batutis, San Jose, CA (US)

(21) Appl. No.: 19/197,322

(22) Filed: May 2, 2025

Related U.S. Application Data
(60) Provisional application No. 63/643,181, filed on May 6, 2024.

(51) Int. Cl. G11C 29/00; G11C 16/26

(52) U.S. Cl. CPC G11C 29/789; G11C 16/26; G11C 29/886

(57) ABSTRACT

The present disclosure configures a memory sub-system controller to read virtual blocks using partial good block (PGBs) across different planes using different read voltages. The controller identifies a region of a set of memory components, the region comprising a plurality of planes across a plurality of decks of the set of memory components. The controller generates an individual virtual block (VB) using a first PGB on a first deck of the plurality of decks of the region associated with a first plane of the plurality of planes and a second PGB on a second deck of the plurality of decks associated with the first plane. The controller, in response to receiving the request to read the data, applies a first read voltage offset to read the individual VB from the first plane in parallel with applying a second read voltage offset to read an additional VB from a second plane.

### PRIORITY APPLICATION

This application claims the benefit of priority to U.S. Provisional Application Ser. No. 63/643,181, filed May 6, 2024, which is incorporated herein by reference in its entirety.

### TECHNICAL FIELD

Examples of the disclosure relate generally to memory sub-systems and, more specifically, to providing adaptive media management for memory components, such as memory dies.

### BACKGROUND

A memory sub-system can be a storage system, such as a solid-state drive (SSD), and can include one or more memory components that store data. The memory components can be, for example, non-volatile memory components and volatile memory components. In general, a host system can utilize a memory sub-system to store data on the memory components and to retrieve data from the memory components.

### BRIEF DESCRIPTION OF THE DRAWINGS

The present disclosure will be understood more fully from the detailed description given below and from the accompanying drawings of various embodiments of the disclosure.

FIG. 1 is a block diagram illustrating an example computing environment including a memory sub-system, in accordance with some examples.

FIG. 2 is a block diagram of an example media operations manager, in accordance with some examples.

FIG. 3 is a block diagram of example virtual blocks made up of partial good blocks (PGBs) and full blocks (FBs), in accordance with some examples.

FIG. 4 is a block diagram of example read compensation table for accessing data using different read voltages across multiple planes, in accordance with some examples.

FIGS. 5A and 5B are flow diagrams of example methods to perform memory operations to access virtual blocks across multiple planes, in accordance with some examples.

FIG. 6 is a block diagram illustrating a diagrammatic representation of a machine in the form of a computer system within which a set of instructions can be executed for causing the machine to perform any one or more of the methodologies discussed herein, in accordance with some examples.

### DETAILED DESCRIPTION

Aspects of the present disclosure configure a system component, such as a memory sub-system controller, to combine multiple PGBs (also referred to as half good blocks [HGBs]) and/or portions of FBs to form one or more virtual blocks (VBs). Specifically, the memory controller can generate a VB using various combinations of FBs. One of the FBs used to generate the VB can be made up of a first PGB in a first deck (e.g., an upper deck) of a memory component and a second PGB in a second deck (e.g., a lower deck) of the memory component. Another one of the FBs used to generate the same VB can be made up of some but not all (e.g., less than all) portions of an individual FB within one of the decks (e.g., the first deck) combined with another PGB in another one of the decks (e.g., the second deck) or some but not all portions of another FB in the other one of the decks (e.g., the second deck). To read the data stored in the VB across multiple planes different read levels can be used. This way, different read levels can be applied in parallel to read the data stored across the different planes. The read levels can be determined and set based on the number of pages and/or word lines (WLs) that are in an erased state in a given FB, PGB, and/or memory portion being read. This improves the overall efficiency of operating the memory sub-system by utilizing memory blocks even if they include PGBs (e.g., contain some defective word line groups [WGRs]) and enabling reading such PGBs accurately using different read voltages on different planes in parallel.

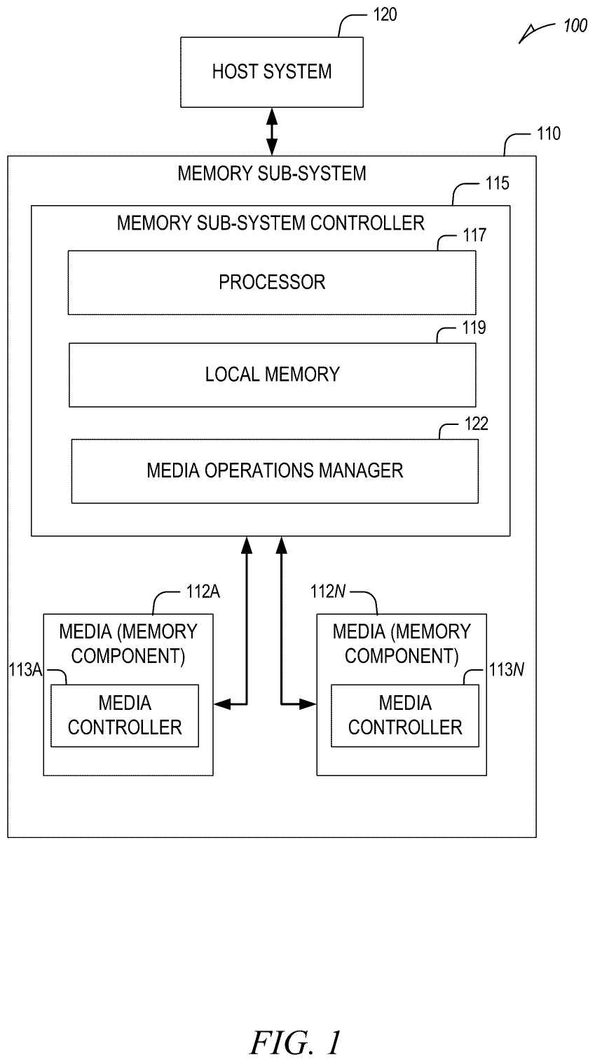

A memory sub-system can be a storage device, a memory module, or a hybrid of a storage device and memory module. Examples of storage devices and memory modules are described below in conjunction with FIG. 1. In general, a host system can utilize a memory sub-system that includes one or more memory components, such as memory devices (e.g., memory dies) that store data. The host system can send access requests (e.g., write command, read command) to the memory sub-system, such as to store data at the memory sub-system and to read data from the memory sub-system. The data (or set of data) specified by the host is hereinafter referred to as “host data,” “application data,” or “user data”.

The memory sub-system can initiate media management operations, such as a write operation, on host data that is stored on a memory device. For example, firmware of the memory sub-system may re-write previously written host data from a location on a memory device to a new location as part of garbage collection management operations. The data that is re-written, for example as initiated by the firmware, is hereinafter referred to as “garbage collection data”. “User data” can include host data and garbage collection data. “System data” hereinafter refers to data that is created and/or maintained by the memory sub-system for performing operations in response to host requests and for media management. Examples of system data include, and are not limited to, system tables (e.g., logical-to-physical address mapping table), data from logging, scratch pad data, etc.

Many different media management operations can be performed on the memory device. For example, the media management operations can include different scan rates, different scan frequencies, different wear leveling, different read disturb management, different near miss error correction (ECC), and/or different dynamic data refresh. Wear leveling ensures that all blocks in a memory component approach their defined erase-cycle budget at the same time, rather than some blocks approaching it earlier. Read disturb management counts all of the read operations to the memory component. If a certain threshold is reached, the surrounding regions are refreshed. Near-miss ECC refreshes all data read by the application that exceeds a configured threshold of errors. Dynamic data-refresh scan reads all data and identifies the error status of all blocks as a background operation. If a certain threshold of errors per block or ECC unit is exceeded in this scan-read, a refresh operation is triggered.

A memory device can be a non-volatile memory device. A non-volatile memory device is a package of one or more dice (or dies). Each die can be comprised of one or more planes. For some types of non-volatile memory devices (e.g., NAND devices), each plane is comprised of a set of physical blocks. For some memory devices, blocks are the smallest area that can be erased. Each block is comprised of a set of pages. Each page is comprised of a set of memory cells, which store bits of data. The memory devices can be raw memory devices (e.g., NAND), which are managed externally, for example, by an external controller. The memory devices can be managed memory devices (e.g., managed NAND), which is a raw memory device combined with a local embedded controller for memory management within the same memory device package.

Typical memory systems leverage VBs, also referred to as superblocks, which are a collection of blocks across multiple memory planes, decks (e.g., upper decks and lower decks), and/or dies. Namely, each superblock can be of equal size and can include a respective collection of blocks across multiple planes, decks, and/or dies. The superblocks, when allocated, allow a controller to simultaneously write data to a large portion of memory spanning multiple blocks (across multiple planes, decks, and/or dies) with a single address. For example, the VBs are usually made up of blocks from an upper deck and a lower deck of the WGRs of the memory components. If any WGR in the upper deck is defective, the conventional systems can utilize the WGRs from the lower deck or vice versa. This can avoid wasting memory resources. In some cases, portions of the blocks can be defective while other portions of the same blocks can be non-defective. Data can be written to the non-defective portions of these blocks. Such blocks are referred to as PGBs.

The PGBs can be on the upper deck and/or the lower deck of the memory devices. Typical memory systems can form virtual blocks by combining multiple PGBs from one deck with multiple PGBs from another deck. For example, the virtual block can be formed by combining a first set of PGBs across a plurality of planes of a first deck of a memory component with a second set of PGBs across the planes of a second deck of the memory component. However, when reading data across multiple planes in parallel, these systems apply the same read level voltage offset which can increase the read bit error rate (RBER) of the data being read. This is because data from blocks that have a greater number of portions (e.g., WLs, WGRs, blocks, pages, and so forth) that are in the erased state may need to be read using higher read threshold voltages than other portions. Applying the same read level offset across each of the planes being read in parallel fails to account for the erase states and results in increased RBER. This can reduce the efficiency of reading superblocks because additional error handing may need to be performed which consumes systems resources and introduces read delays. This can result in poor or unreliable memory performance.

Aspects of the present disclosure address the above and other deficiencies by providing a memory controller that can read superblocks or VBs across different planes in parallel using different read threshold voltage offsets for each plane. Namely, one plane can be read using a first read threshold voltage offset in parallel with another plane read using a different second read threshold voltage offset. This reduces the RBER associated with reading data stored in PGBs which improves the overall efficiency of operating the memory sub-system by reducing the possible need to perform error handling and reducing read delays.

In some examples, the memory controller identifies a region of the set of memory components. The region can include a plurality of planes across a plurality of decks of the set of memory components. The memory controller generates an individual virtual block (VB) using a first partial good block (PGB) on a first deck of the plurality of decks of the region associated with a first plane of the plurality of planes and a second PGB on a second deck of the plurality of decks associated with the first plane. The memory controller receives a request to read data stored in the region of the set of memory components and, in response, applies a first read voltage offset to read the individual VB from the first plane in parallel with applying a second read voltage offset to read an additional VB from a second plane of the plurality of planes.

The VB can be generated using less than all portions of a full block (FB). The first PGB can include a first portion categorized as being defective and a second portion categorized as being non-defective. The first PGB can be formed using less than all portions of a full block categorized as being non-defective. The first deck can be an upper deck of the region of the set of memory components and the second deck can be a lower deck of the region of the set of memory components.

The memory controller can combine the first PGB and the second PGB to form the VB. In some cases, the memory controller stores an independent offset for each plane of the plurality of planes and for each deck of the plurality of decks, the independent offset indicating valid addresses for performing memory operations associated with memory blocks on respective planes of the plurality of planes and respective decks of the plurality of decks. The memory operations can include at least one of programming data to the memory blocks, reading data from the memory blocks, or performing garbage collection operations on data stored in the memory blocks.

In some examples, the memory controller receives an additional request to read data from a memory address of the region. The memory controller determines whether data associated with the memory address being read from any of the plurality of planes includes one or more PGBs. In some cases, the memory controller, in response to determining that the data being read from the plurality of planes excludes the one or more PGBs, applies a same voltage offset to read the data from each of the plurality of planes in parallel. The same voltage offset can be computed based on a last written page (e.g., a location of the last written page) associated with the plurality of planes. This can be informative of the number of pages or memory portions that are currently in the erased state.

The memory controller, in response to determining that the data being read from the plurality of planes includes the one or more PGBs, applies different voltage offsets to read the data from each of the plurality of planes in parallel. An individual voltage offset of the different voltage offsets can be computed based on a last written page associated with the plurality of planes. In some cases, the memory controller determines that the one or more PGBs include an individual PGB on the first deck. In such cases, the memory controller obtains information associated with the last written page on the first deck and computes the individual voltage offset based on the obtained information associated with the last written page on the first deck.

The memory controller determines that the one or more PGBs include an individual PGB on the second deck. In such cases, the memory controller obtains information associated with the last written page on the second deck and computes the individual voltage offset based on the obtained information associated with the last written page on the second deck. The memory controller stores a table that represents a number of word lines (WLs) that are in an erased state in a first full block (FB) of the first plane used to form the first PGB. The first read voltage offset can be computed based on the number of WLs that are in the erased state in the first FB of the first plane used to form the first PGB.

Though various examples are described herein as being implemented with respect to a memory sub-system (e.g., a controller of the memory sub-system), some or all of the portions of an example can be implemented with respect to a host system, such as a software application or an operating system of the host system.

FIG. 1 illustrates an example computing environment 100 including a memory sub-system 110, in accordance with some examples of the present disclosure. The memory sub-system 110 can include media, such as memory components 112A to 112N (also hereinafter referred to as “memory devices”). The memory components 112A to 112N can be volatile memory devices, non-volatile memory devices, or a combination of such. The memory components 112A to 112N can be implemented by individual dies, such that a first memory component 112A can be implemented by a first memory die (or a first collection of memory dies) and a second memory component 112N can be implemented by a second memory die (or a second collection of memory dies).

In some examples, the first memory component 112A, block or page of the first memory component 112A, or group of memory components including the first memory component 112A can be associated with a first reliability (capability) grade, value or measure. The terms “reliability grade,” “value” and “measure” are used interchangeably throughout and can have the same meaning. The second memory component 112N or group of memory components including the second memory component 112N can be associated with a second reliability (capability) grade, value or measure. In some examples, each memory component 112A to 112N can store respective configuration data that specifies the respective reliability grade. In some examples, a memory or register can be associated with all of the memory components 112A to 112N, which can store a table that maps different groups, bins or sets of the memory components 112A to 112N to respective reliability grades.

In some examples, a PGB within the first memory component 112A can be grouped with a PGB within the second memory component 112N to form a superblock or VB that has a predetermined, reference or threshold quantity of blocks and WGRs. The PGB within the first memory component 112A can be on the upper deck of the first memory component 112A and the PGB within the second memory component 112N can be on the lower deck of the second memory component 112N. The PGB within the second memory component 112N can be on the same plane or a different plane from the PGB within the first memory component 112A. VBs can be addressed collectively using a single address. In such cases, a logical-to-physical address (LTP or L2P) table can store the association between the single address and each of the PGBs of the first memory component 112A and second memory component 112N associated with that single address. In some cases, a multi-plane read operation can be performed. In such cases, multiple planes of the memory components 112A to 112N can be read in parallel using the same or different read threshold voltage levels/offsets.

In some examples, some of the WGRs of a given block within the first memory component 112A can have reliability grades that are below a threshold or can be characterized as defective or non-defective. Such blocks can be processed to determine whether a quantity of the WGRs that are non-defective relative to the total quantity of WGRs of the block is greater a minimum or reference percentage threshold. Alternatively, or in addition, such blocks can be processed to determine whether a quantity of the WGRs that are defective relative to the total quantity of WGRs of the block is below a minimum or reference percentage threshold. If the quantity of the WGRs that are non-defective relative to the total quantity of WGRs of the block is greater than a minimum or reference percentage threshold, such a block is marked as a PGB and can be used to form a VB. A memory or table can be generated to list the PGBs and their respective WGRs that are defective or non-defective.

In some examples, a VB can be formed by combining a first set of PGBs across a plurality of planes (e.g., four planes P0-P3) of the first memory component 112A with at least a portion of a FB of a second memory component 112N. Specifically, a first group of PGBs on a first subset of planes (e.g., planes P0-P2) on a lower deck of the second memory component 112N can be combined with a portion of the FB on a remaining plane of the plurality of planes (e.g., plane P3) and that is on the lower deck of the second memory component 112N. The first group of PGBs combined with the portion of the FB can be combined with the first set of PGBs of the first memory component 112A to form the VB. In this way, even though the second memory component 112N has PGBs on less than all of its planes, the PGBs and portions of the FBs of the second memory component 112N can be used to generate the VB with the first memory component 112A.

In some examples, a VB can be formed by combining a first PGB on the upper deck of a first plane (e.g., plane P1) of a plurality of planes (e.g., four planes P0-P3) of the first memory component 112A with at least a portion of a FB or a second PGB of the first memory component 112A on a lower deck of the first plane. The first and second PGBs on the first plane can be combined with one or more FBs on the remaining planes (e.g., planes P0, P2, and P3) of the first memory component 112A and/or second memory component 112N to form the VB. In such cases, a first read threshold voltage can be applied (e.g., using a first offset) to read data stored in the first and second PGBs of the first plane (e.g., plane P1) in parallel with applying a second read threshold voltage to read the data stored in the FBs of the remaining planes (e.g., planes P0, P2, and P3).

In some examples, a VB can be formed by combining a first set of PGBs across a plurality of planes (e.g., four planes P0-P3) of the first memory component 112A with at least a portion of multiple FBs of a second memory component 112N. Specifically, a first group of PGBs on a second subset of planes (e.g., planes P0-P1) on a lower deck of the second memory component 112N can be combined with a portion of a first FB on a first remaining plane of the plurality of planes (e.g., plane P2) and that is on the lower deck of the second memory component 112N. Also, the first group of PGBs on the second subset of planes (e.g., planes P0-P1) on the lower deck of the second memory component 112N and the portion of the first FB can be combined with a portion of a second FB on a second remaining plane of the plurality of planes (e.g., plane P3) and that is on the lower deck of the second memory component 112N. The first group of PGBs combined with the portions of the first and second FBs can be combined with the first set of PGBs of the first memory component 112A to form the VB.

In some examples, a VB can be formed by combining a first set of PGBs across a first subset of a plurality of planes (e.g., planes P0-P1) of the first memory component 112A with at least a portion of multiple PGBs of the second memory component 112N and with other FBs of the first memory component 112A across a second subset of the plurality of planes (e.g., planes P2-P3). Specifically, a first group of PGBs on the first subset of planes (e.g., planes P0-P1) on a lower deck of the second memory component 112N can be combined with the first set of PGBs across the first subset of planes of the first memory component 112A. The VB can also be formed by combining other FBs (e.g., a first FB on a first remaining plane, such as plane P2 and a second FB on a second remaining plane, such as plane P3 of the first or second memory component 112A or 112N) with the combined first group of PGBs and first set of PGBs.

In some examples, the VB that is formed can be of a size that is smaller than a superblock. In such cases, the VB can be formed by combining multiple FBs across a first set of planes of the first memory component 112A with one or more PGBs on a second set of planes of the first memory component 112A. In such cases, the PGBs can be on any deck (upper or lower) of the first memory component 112A and can be combined with the FBs on the other planes to form the VB that is smaller than other superblocks. In these circumstances, a table can be maintained that identifies the logical block addresses (LBAs) and/or addresses of such VBs that are of smaller sizes than superblocks. The table can specify which plane of the VB includes the PGB on only one deck (e.g., the plane of the VB that makes the VB smaller than the superblock because the PGB from one deck is not combined with the PGB from another deck).

In some examples, the memory sub-system 110 is a storage system. A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and a non-volatile dual in-line memory module (NVDIMM).

The computing environment 100 can include a host system 120 that is coupled to a memory system. The memory system can include one or more memory sub-systems 110. In some embodiments, the host system 120 is coupled to different types of memory sub-system 110. FIG. 1 illustrates one example of a host system 120 coupled to one memory sub-system 110. The host system 120 uses the memory sub-system 110, for example, to write data to the memory sub-system 110 and read data from the memory sub-system 110. As used herein, “coupled to” generally refers to a connection between components, which can be an indirect communicative connection or direct communicative connection (e.g., without intervening components), whether wired or wireless, including connections such as electrical, optical, magnetic, etc.

The host system 120 can be a computing device such as a desktop computer, laptop computer, network server, mobile device, embedded computer (e.g., one included in a vehicle, industrial equipment, or a networked commercial device), or such computing device that includes a memory and a processing device. The host system 120 can include or be coupled to the memory sub-system 110 so that the host system 120 can read data from or write data to the memory sub-system 110. The host system 120 can be coupled to the memory sub-system 110 via a physical host interface. Examples of a physical host interface include, but are not limited to, a serial advanced technology attachment (SATA) interface, a peripheral component interconnect express (PCIe) interface, a compute express link (CXL), a universal serial bus (USB) interface, a Fibre Channel interface, a Serial Attached SCSI (SAS) interface, etc. The physical host interface can be used to transmit data between the host system 120 and the memory sub-system 110. The host system 120 can further utilize an NVM Express (NVMe) interface to access the memory components 112A to 112N when the memory sub-system 110 is coupled with the host system 120 by the PCIe or CXL interface. The physical host interface can provide an interface for passing control, address, data, and other signals between the memory sub-system 110 and the host system 120.

The memory components 112A to 112N can include any combination of the different types of non-volatile memory components and/or volatile memory components. An example of non-volatile memory components includes a negative- and (NAND)-type flash memory. Each of the memory components 112A to 112N can include one or more arrays of memory cells such as single-level cells (SLCs) or multi-level cells (MLCs) (e.g., TLCs or QLCs). In some embodiments, a particular memory component 112 can include both an SLC portion and an MLC portion of memory cells. Each of the memory cells can store one or more bits of data (e.g., blocks) used by the host system 120. Although non-volatile memory components such as NAND-type flash memory are described, the memory components 112A to 112N can be based on any other type of memory, such as a volatile memory. In some embodiments, the memory components 112A to 112N can be, but are not limited to, random access memory (RAM), read-only memory (ROM), dynamic random access memory (DRAM), synchronous dynamic random access memory (SDRAM), phase change memory (PCM), magnetoresistive random access memory (MRAM), negative-or (NOR) flash memory, electrically erasable programmable read-only memory (EEPROM), and a cross-point array of non-volatile memory cells. A cross-point array of non-volatile memory cells can perform bit storage based on a change of bulk resistance, in conjunction with a stackable cross-gridded data access array.

Additionally, in contrast to many flash-based memories, cross-point non-volatile memory can perform a write-in-place operation, where a non-volatile memory cell can be programmed without the non-volatile memory cell being previously erased. Furthermore, the memory cells of the memory components 112A to 112N can be grouped as memory pages or blocks that can refer to a unit of the memory component 112 used to store data. For example, a single first row that spans memory components 112A to 112N can correspond to or be grouped as a first superblock and a single second row that spans memory components 112A to 112N can correspond to or be grouped as a second superblock. If the single first row includes all good blocks (e.g., each block in the single first row has a reliability grade above a threshold), the first superblock is a first complete superblock. If the single first row includes some bad blocks (e.g., one or more blocks in the single first row have a reliability grade below a threshold), the first superblock is a first incomplete superblock.

The memory sub-system controller 115 can communicate with the memory components 112A to 112N to perform memory operations such as reading data, writing data, or erasing data at the memory components 112A to 112N and other such operations. The memory sub-system controller 115 can communicate with the memory components 112A to 112N to perform various memory management operations, such as different scan rates, different scan frequencies, different wear leveling, different read disturb management, different near miss ECC operations, and/or different dynamic data refresh.

The memory sub-system controller 115 can include hardware such as one or more integrated circuits and/or discrete components, a buffer memory, or a combination thereof. The memory sub-system controller 115 can be a microcontroller, special-purpose logic circuitry (e.g., a field programmable gate array (FPGA), an application specific integrated circuit (ASIC), etc.), or another suitable processor. The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120. In some embodiments, the local memory 119 can include memory registers storing memory pointers, fetched data, and so forth. The local memory 119 can also include read-only memory (ROM) for storing microcode. While the example memory sub-system 110 in FIG. 1 has been illustrated as including the memory sub-system controller 115, in another embodiment of the present disclosure, a memory sub-system 110 may not include a memory sub-system controller 115, and can instead rely upon external control (e.g., provided by an external host, or by a processor 117 or controller separate from the memory sub-system 110).

In general, the memory sub-system controller 115 can receive commands or operations from the host system 120 and can convert the commands or operations into instructions or appropriate commands to achieve the desired access to the memory components 112A to 112N. In some examples, the commands or operations received from the host system 120 can specify configuration data for the memory components 112N to 112N. The configuration data can describe the reliability grades and/or indications of defects in certain WGRs associated with different groups of the memory components 112N to 112N and/or different blocks within each of the memory components 112N to 112N. In some cases, the reliability grades are dynamic and can be updated by the memory sub-system controller 115 in response to determining that certain error rates are reached that transgress an error rate threshold. For example, a non-defective WGR can become a defective WGR if that non-defective WGR starts having error rates that transgress the threshold. In such cases, the configuration data is updated and any VB that includes that now defective WGR is updated with a replacement or spare PGB to maintain performance of the VB above a minimum or reference performance rating.

The memory sub-system controller 115 can be responsible for other memory management operations, such as wear leveling operations, garbage collection operations, error detection and error-correcting code (ECC) operations, encryption operations, caching operations, and address translations. The memory sub-system controller 115 can further include host interface circuitry to communicate with the host system 120 via the physical host interface. The host interface circuitry can convert the commands received from the host system 120 into command instructions to access the memory components 112A to 112N as well as convert responses associated with the memory components 112A to 112N into information for the host system 120.

The memory sub-system 110 can also include additional circuitry or components that are not illustrated. In some embodiments, the memory sub-system 110 can include a cache or buffer (e.g., DRAM or other temporary storage location or device) and address circuitry (e.g., a row decoder and a column decoder) that can receive an address from the memory sub-system controller 115 and decode the address to access the memory components 112A to 112N.

The memory devices can be raw memory devices (e.g., NAND), which are managed externally, for example, by an external controller (e.g., memory sub-system controller 115). The memory devices can be managed memory devices (e.g., managed NAND), which is a raw memory device combined with a local embedded controller (e.g., local media controllers) for memory management within the same memory device package. Any one of the memory components 112A to 112N can include a media controller (e.g., media controller 113A and media controller 113N) to manage the memory cells of the memory component (e.g., to perform one or more memory management operations), to communicate with the memory sub-system controller 115, and to execute memory requests (e.g., read or write) received from the memory sub-system controller 115.

The memory sub-system controller 115 can include a media operations manager 122. The media operations manager 122 can be configured to combine multiple PGBs (on the same or different planes and/or decks) and portions of FBs across multiple planes and decks of multiple memory components to form one or more VBs. The memory sub-system controller 115 can access configuration data associated with a set of memory components. The configuration data can include a table that associates different WGRs of blocks of the memory components with indications of whether the WGRs are defective or non-defective. Based on the configuration data, the memory sub-system controller 115 can identify those PGBs that have a reference or minimum quantity or percentage (e.g., 30%) of WGRs that are non-defective. The memory sub-system controller 115 can then combine multiple such PGBs with various portions of FBs to form one or more VBs. This improves the overall efficiency of operating the memory sub-system by utilizing memory blocks even if they contain some defective WGRs. This increases the efficiency of operating memory systems. In some cases, the configuration data stores a read compensation table.

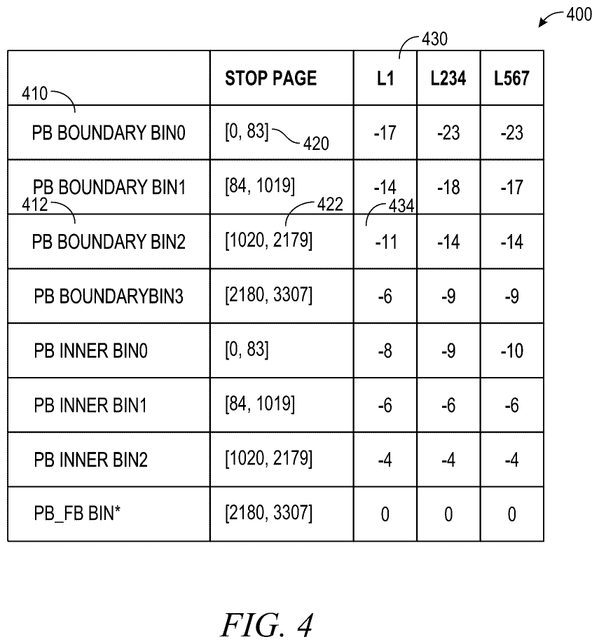

For example, as shown in FIG. 4, a read compensation table 400 can be maintained. The read compensation table 400 can associate different numbers of pages in the erase state of individual VBs, FBs, and/or PGBs with different read levels or read threshold voltage offsets. For example, a first PGB boundary 410 can identify a first range of pages 420 that have been programmed. This indicates the quantity of pages of the PGB that have been programmed and/or the quantity of pages that remain in the erase state. The first PGB boundary 410 can be associated with a first set of read threshold voltage offsets 430. A second PGB boundary 412 can identify a second range of pages 422 that have been programmed which can represent a greater quantity of programmed pages than the first VB boundary 410. Namely, the second PGB boundary 412 can be associated with a smaller portion of the set of memory components 112A to 112N that is in an erased state than that which is associated with the first PGB boundary 410. In such cases, the second PGB boundary 412 can be associated with a second set of read threshold voltage offsets 434 that are lower than the first set of read threshold voltage offsets 430.

In some examples, the memory sub-system controller 115 (e.g., the media operations manager 122) identifies a region of a set of memory components, the region including a plurality of planes across a plurality of decks of the set of memory components. The memory sub-system controller 115 generates an individual VB using a first PGB on a first deck of the plurality of decks of the region associated with a first plane of the plurality of planes and a second PGB on a second deck of the plurality of decks associated with the first plane. The memory sub-system controller 115, in response to receiving the request to read the data, applies a first read voltage offset to read the individual VB from the first plane in parallel with applying a second read voltage offset to read an additional VB from a second plane.

Depending on the example, the media operations manager 122 can comprise logic (e.g., a set of transitory or non-transitory machine instructions, such as firmware) or one or more components that causes the media operations manager 122 to perform operations described herein. The media operations manager 122 can comprise a tangible or non-tangible unit capable of performing operations described herein. Further details with regards to the operations of the media operations manager 122 are described below.

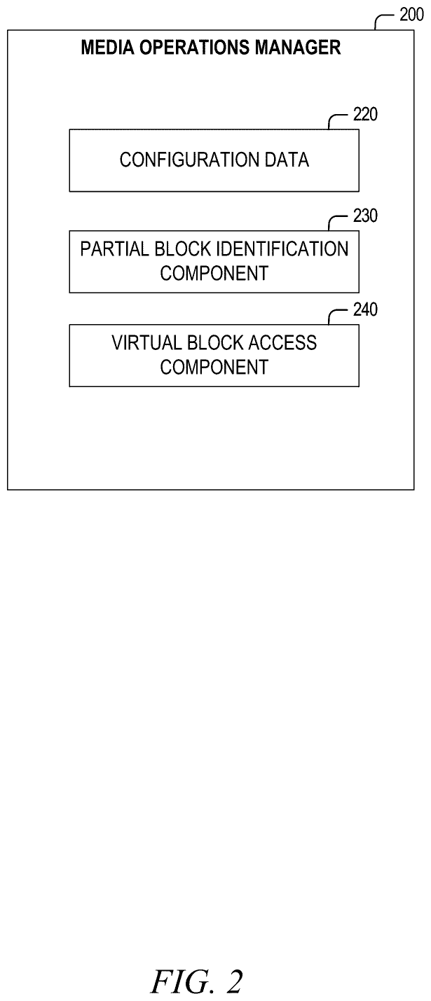

FIG. 2 is a block diagram of an example media operations manager 200, in accordance with some examples. The media operations manager 200 can include some or all of the components of the media operations manager 122, shown in FIG. 1. As illustrated, the media operations manager 122 includes configuration data 220, a partial block identification component 230, and a virtual block access component 240. For some examples, the media operations manager 122 can differ in components or arrangement (e.g., less or more components) from what is illustrated in FIG. 2.

The configuration data 220 accesses and/or stores configuration data associated with the memory components 112A to 112N. In some examples, the configuration data 220 is programmed into the media operations manager 122 during manufacture of the memory sub-system 110. The media operations manager 122 can communicate with the memory components 112A to 112N to obtain the configuration data and store the configuration data 220 locally on the media operations manager 122. In some examples, the media operations manager 122 communicates with the host system 120. The host system 120 receives input from an operator or user that specifies parameters including indications of defects present on different WGRs, different bins, groups, blocks, or sets of the memory components 112A to 112N. The media operations manager 122 receives configuration data from the host system 120 and stores the configuration data in the configuration data 220. The configuration data 220 can store the read compensation table 400 of FIG. 4.

In some examples, the media operations manager 122 performs one or more test operations on different groups or blocks of the memory components 112A to 112N. The test operations are configured to determine and detect which WGRs have recoverable defects (are non-defective) and which WGRs have non-recoverable defects (are defective) of each block of the memory components 112A to 112N. Recoverable defects include at least one of word line (WL) to WL shorts, open WL, a slow to program WL, or a WL that fails to satisfy read bit error rate thresholds. Non-recoverable defects include at least one of word line (WL) to pillar shorts, source-to-gate (SG) shorts, or dummy WL shorts.

Based on a result of the test operations, the media operations manager 122 can store or update the PGB identified in the configuration data 220. In some examples, the media operations manager 122 can periodically or routinely perform the test operations to update which WGRs change from being non-defective to being defective resulting in failure of the PGB. The configuration data 220 can also store a reference or minimum threshold percentage of non-defective WGRs an individual block can have to be usable as a PGB.

In some examples, the partial block identification component 230 accesses the configuration data 220 to generate a list of PGBs. In such cases, the partial block identification component 230 can obtain from the configuration data 220 the list of WGRs and their respective indications of types of defects (e.g., recoverable or non-recoverable). The partial block identification component 230 can determine for an individual block the quantity of WGRs having recoverable defects. The partial block identification component 230 can compute the total quantity of WGRs (having the recoverable and non-recoverable defects) of the individual block. The partial block identification component 230 can compute a ratio or percentage of the quantity of WGRs having recoverable defects to the total quantity of WGRs. The partial block identification component 230 can obtain the reference or minimum threshold percentage of non-defective WGRs an individual block can have to be usable as a PGB from the configuration data 220. The partial block identification component 230 can determine that the ratio or percentage of the quantity of WGRs having recoverable defects to the total quantity of WGRs transgresses the reference or minimum threshold percentage of non-defective WGRs (e.g., 30%). In such cases, the partial block identification component 230 can add the individual block to a list of PGBs by storing an address of the block corresponding to the PGB and the list of WGRs having non-recoverable defects or that are defective. If the ratio or percentage of the quantity of WGRs having recoverable defects to the total quantity of WGRs fails to transgress the reference or minimum threshold percentage, the individual block is discarded and is excluded from the list of PGBs to avoid using the block as a PGB used to form a VB.

The partial block identification component 230 can continue processing all of the blocks of the memory components 112A-112N in a similar manner to compile a list of all PGBs for which a quantity of WGRs that are non-defective relative to a total number of WGRs transgresses a reference or threshold percentage. In some examples, in response to determining that the ratio or percentage of the quantity of WGRs having recoverable defects to the total quantity of WGRs transgresses the reference or minimum threshold percentage of non-defective WGRs (e.g., 30%), the partial block identification component 230 can perform additional reliability tests on the remaining WGRs that are non-defective. The partial block identification component 230 can determine that the remaining WGRs of the individual block pass the additional reliability tests. For example, the partial block identification component 230 can determine that a read bit error rate (RBER) for the WGRs that are non-defective is below a reference RBER. If the remaining WGRs of the individual block pass the additional reliability tests, the PGB is maintained or added to the list of PGBs. If the remaining WGRs of the individual block fail the additional reliability tests, the individual block is discarded and is excluded from the list of PGBs to avoid using the block as a PGB used to form a VB.

After the list of PGBs is generated, the virtual block access component 240 can access the list of PGBs to form one or more VBs using different groups of PGBs that are in the list and using various FBs on different planes and/or decks of the memory components 112A to 112N. For example, the virtual block access component 240 can form an individual VB by combining a first set of PGBs across a plurality of planes (e.g., four planes P0-P3) of the first memory component 112A with at least a portion of a FB of a second memory component 112N. Specifically, a first group of PGBs on a first subset of planes (e.g., planes P0-P2) on a lower deck of the second memory component 112N can be combined with a portion of the FB on a remaining plane of the plurality of planes (e.g., plane P3) and that is on the lower deck of the second memory component 112N. The first group of PGBs combined with the portion of the FB can be combined with the first set of PGBs of the first memory component 112A to form the VB. As another example, the virtual block access component 240 can form or generate a VB that includes FBs on a first set of planes (e.g., planes P0-P3) and PGBs that are on different decks of an individual plane (e.g., plane P4).

In some examples, combining of different memory portions or regions can be performed by storing LBAs or block addresses of the memory portions or regions in association with an address of the VB. For example, the virtual block access component 240 can store an address of a VB. The virtual block access component 240 can associate with that address the LBAs or block addresses of the first set of PGBs across a plurality of planes (e.g., four planes P0-P3) of the first memory component 112A and the at least a portion of the FB of the second memory component 112N. In this way, when a memory operation is requested to be performed for the VB, the associated LBAs and/or block addresses can be used to access or perform the requested operation on the data.

In some examples, the virtual block access component 240 forms the individual VB by combining a first set of PGBs across a plurality of planes (e.g., four planes P0-P3) of the first memory component 112A with at least a portion of a FB of a second memory component 112N. Specifically, a first group of PGBs on a first subset of planes (e.g., planes P0-P2) on an upper deck of the second memory component 112N can be combined with a portion of the FB on a remaining plane of the plurality of planes (e.g., plane P3) and that is on the upper deck of the second memory component 112N. The first group of PGBs combined with the portion of the FB can be combined with the first set of PGBs of the first memory component 112A to form the VB.

In some examples, the VB that is formed can be of a size that is smaller than a superblock. In such cases, the virtual block access component 240 forms the VB by combining multiple FBs across a first set of planes of the first memory component 112A with one or more PGBs on a second set of planes of the first memory component 112A. In such cases, the PGBs can be on any deck (upper or lower) of the first memory component 112A and can be combined with the FBs on the other planes to form the VB that is smaller than other superblocks. In these circumstances, a table can be maintained that identifies the logical block addresses (LBAs) and/or addresses of such VBs that are of smaller sizes than superblocks. The table can specify which plane of the VB includes the PGB on only one deck (e.g., the plane of the VB that makes the VB smaller than the superblock because the PGB from one deck is not combined with the PGB from another deck).

The virtual block access component 240 can maintain independent offsets for each plane of the plurality of planes and for each deck of the plurality of decks of the memory components 112A to 112N. The independent offset can indicate valid addresses for performing memory operations associated with memory blocks on respective planes of the plurality of planes and respective decks of the plurality of decks.

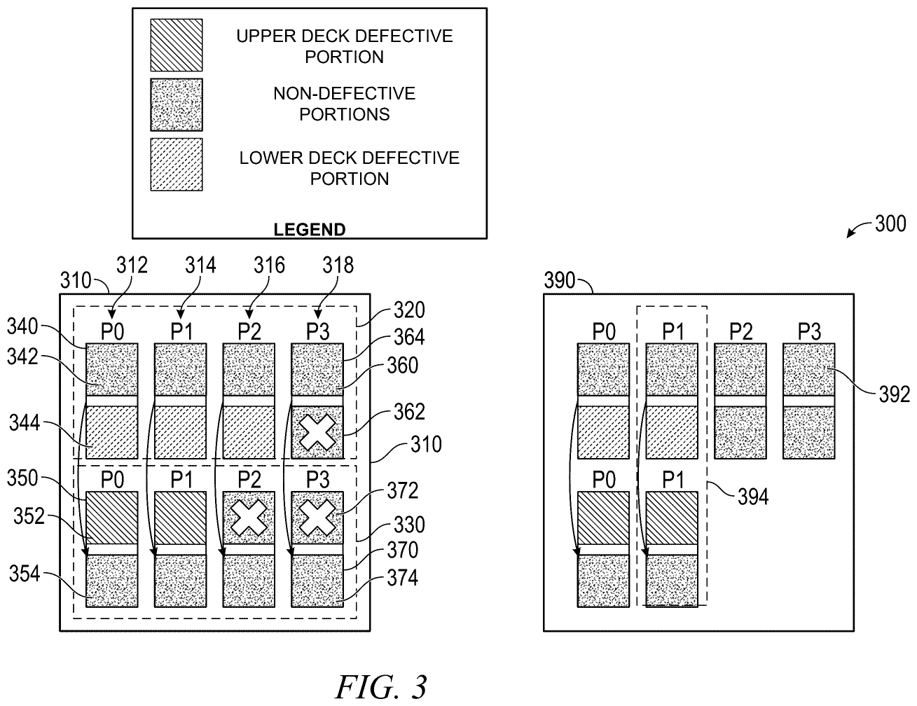

FIG. 3 is a block diagram of an example plurality of VBs 300 made up of PGBs and one or more portions of one or more FBs, in accordance with some examples. Specifically, a first VB 310 can be formed or generated by the virtual block access component 240 by combining different PGBs and/or portions of FBs across multiple planes and decks of multiple memory components 112A to 112N. For example, a first memory component 320 can include a plurality of planes 312, 314, 316, and 318 across multiple decks (e.g., an upper deck and a lower deck) and a second memory component 330 can include a plurality of planes 312, 314, 316, and 318 across multiple decks (e.g., an upper deck and a lower deck). The virtual block access component 240 can determine that the planes 312, 314 and 316 of the first memory component 320 include PGBs 342 on the upper deck. In such cases, the virtual block access component 240 can determine that the lower decks of planes 312, 314, and 316 include defective portions that cannot be accessed. In such cases, to generate a FB to be used in generating a VB, the virtual block access component 240 can combine the PGBs 342 of the first memory component 320 with PGBs 354 (and/or portions of FBs) across the same set of planes of another memory component (e.g., the second memory component 112N).

For example, the virtual block access component 240 can determine that the second memory component 330 includes a block 350 on a first plane 312 that includes a PGB 354 on the lower deck and that includes a defective portion 352 on the upper deck. The virtual block access component 240 can combine the PGBs 342 of the first plane 312 of the first memory component 320 with the PGB 354 of the second memory component 330 that is on the first plane 312 to form a first FB. Similarly, the virtual block access component 240 can combine the PGBs 342 of the second plane 314 of the first memory component 320 with a PGB of the second memory component 330 that is on the second plane 314 to form a second FB. For example, the virtual block access component 240 can determine that the first memory component 320 includes a block 340 on a first plane 312 that includes a PGB on the upper deck and that includes a defective portion 344 on the lower deck. The virtual block access component 240 can combine the PGBs of the first plane 312 of the first memory component 320 with the PGB of the second memory component 330 that is on the first plane 312 to form a first FB.

The virtual block access component 240 can combine the PGBs 342 of the third plane 316 of the first memory component 320 with a portion of a FB of the second memory component 330 within the lower deck of the second memory component 330 and that is on the third plane 316 to form a third FB. The upper deck portion of the FB that is on the third plane 316 of the second memory component 330 can be excluded (indicated by the X in the drawing) from being used at all. The virtual block access component 240 can combine a portion 364 of a FB 360 of the fourth plane 318 on the upper deck portion of the first memory component 320 with a portion 374 of a FB 370 of the second memory component 330 within the lower deck of the second memory component 112N and that is on the fourth plane 318 to form a fourth FB. The lower deck portion 362 of the FB 360 that is on the fourth plane 318 of the first memory component 320 can be excluded (indicated by the X in the drawing) from being used at all. The upper deck portion 372 of the FB 370 that is on the fourth plane 318 of the second memory component 330 can be excluded (indicated by the X in the drawing) from being used at all.

In some examples, the virtual block access component 240 can combine the first, second, third, and fourth FBs that were generated into a single VB 310.

In some examples, a second VB 390 can be formed or generated by the virtual block access component 240 by combining different PGBs and/or portions of FBs across multiple planes and decks of multiple memory components 112A to 112N (e.g., the first memory component 320 and the second memory component 330 or of a single memory component). For example, the virtual block access component 240 can determine that the planes 312 and 314 of the first memory component 320 include PGBs 342 on the upper deck. In such cases, the virtual block access component 240 can determine that the lower decks of planes 312 and 314 include defective portions that cannot be accessed. In such cases, to generate a FB 394 to be used in generating a VB, the virtual block access component 240 can combine the PGBs 342 of the upper deck of the planes 312 and 314 of the first memory component 320 with PGBs 354 (and/or portions of FBs) across the same set of planes of the upper or lower deck of the second memory component 330.

The virtual block access component 240 can add other FBs 392 from the remaining planes (e.g., planes 316 and 318) including portions from both the upper and lower decks of the first memory component 320 and/or the second memory component 330 to form the second VB 390. Specifically, the virtual block access component 240 can combine the FB 394 (generated by combining multiple PGBs of different memory components across the planes 312 and 314) with one or more FBs 392 of the planes 316 and 318.

In some examples, the virtual block access component 240 receives a request to read data from the set of memory components 112A to 112N. In response, the virtual block access component 240 can determine whether an address associated with the request includes any PGBs on any planes of the set of memory components 112A to 112N. The request can be associated with reading a VB from the set of memory components 112A to 112N. In response to determining that the VB of the data being accessed does not include any PGBs, the virtual block access component 240 can read the data from the VB corresponding physical address using the same read threshold voltage offset. Specifically, the virtual block access component 240 can identify a storage location of a last written page of the VB being accessed. The virtual block access component 240 can access the read compensation table 400 to retrieve a corresponding read threshold offset based on the location of the last written page.

For example, if the last written page of the VB is at a storage location that falls within the second range of pages 422 (FIG. 4), the virtual block access component 240 retrieves the second set of read threshold voltage offsets 434. As another example, the virtual block access component 240 can retrieve a default read threshold voltage offset instead of the offset stored in the read compensation table 400 in response to determining that the VB being accessed excludes any PGBs. The virtual block access component 240 then applies the read threshold voltage using the retrieved offset to read the data in parallel from all of the planes (e.g., planes P0-P3) of the set of memory components 112A to 112N.

In some cases, the virtual block access component 240 determines that the VB identified by the request or identified by a subsequent request includes one or more PGBs. For example, the virtual block access component 240 can determine that the VB includes a PGB on an individual plane (e.g., plane P2). In such cases, the virtual block access component 240 determines whether the PGB of the VB is on the upper deck or lower deck of the set of memory components 112A to 112N. In response to determining that the PGB is on the upper deck, the virtual block access component 240 can identify a storage location of a last written page of the VB being accessed on the upper deck. The virtual block access component 240 can access the read compensation table 400 to retrieve a corresponding read threshold offset based on the location of the last written page.

For example, if the last written page of the VB on the upper deck is at a storage location that falls within the first PGB boundary 410, the virtual block access component 240 retrieves the first set of read threshold voltage offsets 430. The virtual block access component 240 computes a first read threshold voltage for reading the data stored in the PGB on the upper deck of the individual plane using the retrieved offset. The virtual block access component 240 then applies the first read threshold voltage to read the data from the individual plane (e.g., plane P2) in parallel with reading the data stored in the remaining plane (e.g., planes P0, P1, and P3) of the set of memory components 112A to 112N using a second read threshold voltage (e.g., a default read threshold voltage).

In some cases, the VB includes PGBs on each of the planes of the set of memory components 112A to 112N. In such cases, the virtual block access component 240 computes multiple read threshold voltages for each plane using the read compensation table 400 (e.g., as a function of the number of pages or portions of the VB on each plane that are in the erased state). The virtual block access component 240 can then read the VB in parallel from each of the planes using different respective ones of the multiple read threshold voltages that have been computed.

In response to determining that the PGB is on the lower deck, the virtual block access component 240 can identify a storage location of a last written page of the VB being accessed on the lower deck. The virtual block access component 240 can access the read compensation table 400 to retrieve a corresponding read threshold offset based on the location of the last written page.

For example, if the last written page of the VB on the lower deck is at a storage location that falls within the first PGB boundary 410, the virtual block access component 240 retrieves the first set of read threshold voltage offsets 430. The virtual block access component 240 computes a first read threshold voltage for reading the data stored in the PGB on the lower deck of the individual plane using the retrieved offset. The virtual block access component 240 then applies the first read threshold voltage to read the data from the individual plane (e.g., plane P2) in parallel with reading the data stored in the remaining plane (e.g., planes P0, P1, and P3) of the set of memory components 112A to 112N using a second read threshold voltage (e.g., a default read threshold voltage).

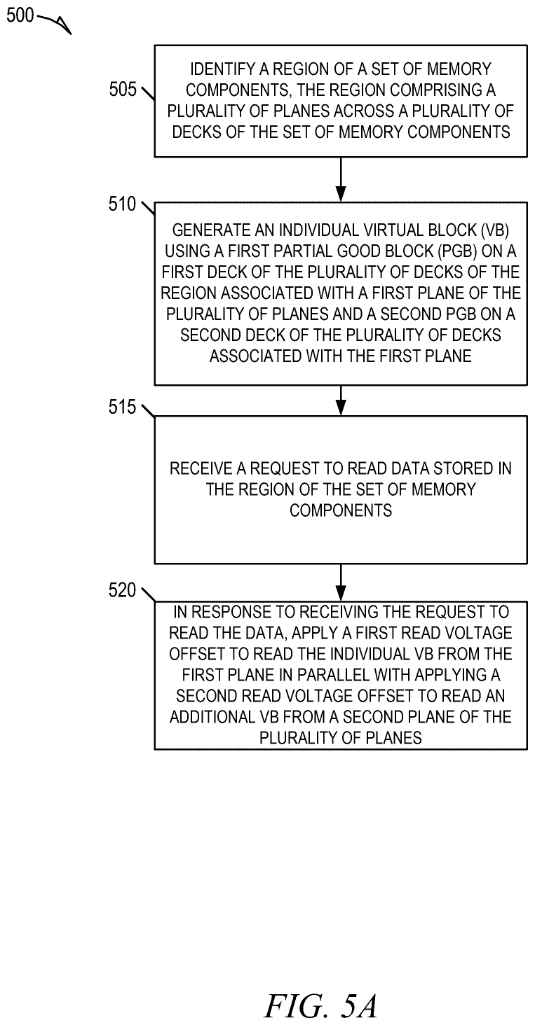

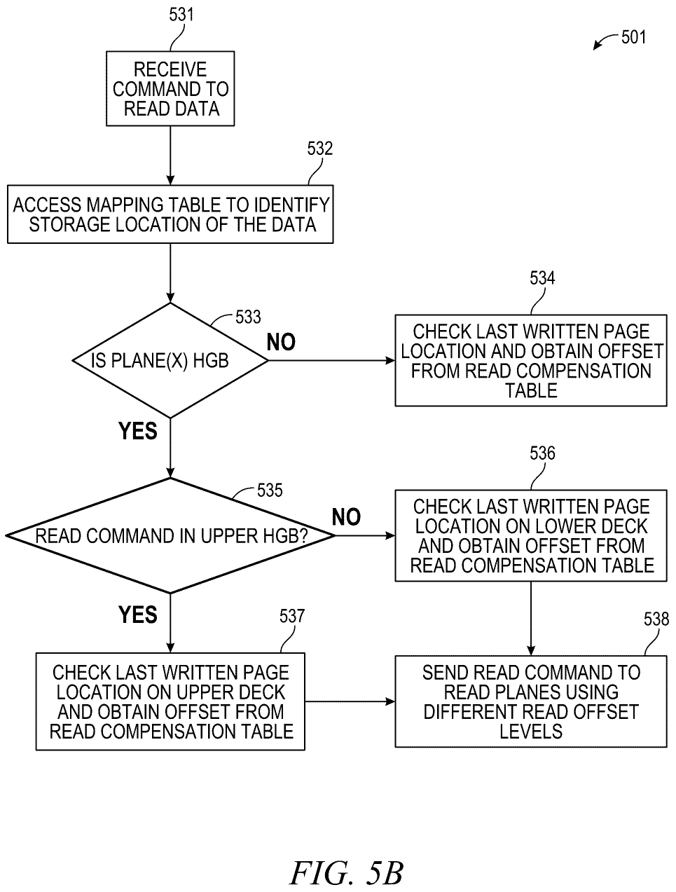

FIGS. 5A and 5B are flow diagrams of an example processes or methods 500 to perform memory operations to access PGBs from multiple planes in parallel, in accordance with some examples. The method 500 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some examples, the method 500 is performed by the media operations manager 122 of FIG. 1. Although the processes are shown in a particular sequence or order, unless otherwise specified, the order of the processes can be modified. Thus, the illustrated examples should be understood only as examples, and the illustrated processes can be performed in a different order, and some processes can be performed in parallel. Additionally, one or more processes can be omitted in various examples. Thus, not all processes are required in every example. Other process flows are possible.

Referring now to FIG. 5A, the method 500 begins at operation 505, with a media operations manager 122 of a memory sub-system (e.g., memory sub-system 110) identifying a region of a set of memory components, the region comprising a plurality of planes across a plurality of decks of the set of memory components. Then, at operation 510, the media operations manager 122 of the memory sub-system generates an individual VB using a first partial good block (PGB) on a first deck of the plurality of decks of the region associated with a first plane of the plurality of planes and a second PGB on a second deck of the plurality of decks associated with the first plane. Thereafter, at operation 515, the media operations manager 122 receives a request to read data stored in the region of the set of memory components. The media operations manager 122, at operation 520, in response to receiving the request to read the data, applies a first read voltage offset to read the individual VB from the first plane in parallel with applying a second read voltage offset to read an additional VB from a second plane of the plurality of planes.

Referring now to FIG. 5B, the method 501 begins at operation 531, with a media operations manager 122 of a memory sub-system (e.g., memory sub-system 110) receiving a command from the host system 120 to read data. The media operations manager 122 accesses a mapping table to identify the physical storage location of the data and to identify the VB that is used to store the data at operation 532. Then, at operation 533, the media operations manager 122 determines if one of the planes of the VB includes a HGB. If so, the media operations manager 122 performs operations 534 and otherwise performs operation 535.

At operation 534, the media operations manager 122 accesses information associated with a last written page (e.g., of the VB being accessed). Based on the information associated with the last written page (e.g., the storage location and/or data that indicates how many pages are still empty in the VB or portion of the VB), the media operations manager 122 obtains a read threshold voltage compensation offset from the read compensation table 400. The media operations manager 122 then reads the VB using the obtained read threshold voltage compensation offset, such as by applying the same read threshold voltage in parallel to all of the planes of the VB.

At operation 535, the media operations manager 122 determines if the HGB of the VB is on the upper deck or lower deck of the planes. In response to determining that the HGB is on the lower deck, the media operations manager 122 performs operations 536 and otherwise performs operation 537. The media operations manager 122 accesses information associated with a last written page (e.g., of the VB being accessed) on the lower deck of the plane that stores the HGB at operation 536. Based on the information associated with the last written page (e.g., the storage location and/or data that indicates how many pages are still empty in the VB or portion of the VB in the lower deck), the media operations manager 122 obtains a read threshold voltage compensation offset from the read compensation table 400. The media operations manager 122 then reads the plane that stores the HGB of the VB using the obtained read threshold voltage compensation offset and remaining planes of the VB using a different (e.g., default) read threshold voltage compensation offset at operation 538.

Similarly, in response to determining that the HGB is on the upper deck, the media operations manager 122 performs operations 537. The media operations manager 122 accesses information associated with a last written page (e.g., of the VB being accessed) on the upper deck of the plane that stores the HGB. Based on the information associated with the last written page (e.g., the storage location and/or data that indicates how many pages are still empty in the VB or portion of the VB in the lower deck), the media operations manager 122 obtains a read threshold voltage compensation offset from the read compensation table 400 at operation 537. The media operations manager 122 then reads the plane that stores the HGB of the VB using the obtained read threshold voltage compensation offset and remaining planes of the VB using a different (e.g., default) read threshold voltage compensation offset at operation 538.

In view of the disclosure above, various examples are set forth below. It should be noted that one or more features of an example, taken in isolation or combination, should be considered within the disclosure of this application.

Example 1. A system comprising: a set of memory components of a memory sub-system; and at least one processing device operatively coupled to the set of memory components, the at least one processing device being configured to perform operations comprising: identifying a region of the set of memory components, the region comprising a plurality of planes across a plurality of decks of the set of memory components; generating an individual virtual block (VB) using a first partial good block (PGB) on a first deck of the plurality of decks of the region associated with a first plane of the plurality of planes and a second PGB on a second deck of the plurality of decks associated with the first plane; receiving a request to read data stored in the region of the set of memory components; and in response to receiving the request to read the data, applying a first read voltage offset to read the individual VB from the first plane in parallel with applying a second read voltage offset to read an additional VB from a second plane of the plurality of planes.

Example 2. The system of Example 1, wherein the VB is generated using less than all portions of a full block (FB).

Example 3. The system of any one of Examples 1-2, wherein the first PGB includes a first portion categorized as being defective and a second portion categorized as being non-defective.

Example 4. The system of any one of Examples 1-3, wherein the first PGB is formed using less than all portions of a full block categorized as being non-defective.

Example 5. The system of any one of Examples 1-4, wherein the first deck is an upper deck of the region of the set of memory components, and wherein the second deck is a lower deck of the region of the set of memory components.

Example 6. The system of any one of Examples 1-5, the operations comprising: combining the first PGB and the second PGB to form the virtual block.

Example 7. The system of any one of Examples 1-6, the operations comprising: storing an independent offset for each plane of the plurality of planes and for each deck of the plurality of decks, the independent offset indicating valid addresses for performing memory operations associated with memory blocks on respective planes of the plurality of planes and respective decks of the plurality of decks.

Example 8. The system of Example 7, wherein the memory operations comprise at least one of programming data to the memory blocks, reading data from the memory blocks, or performing garbage collection operations on data stored in the memory blocks.

Example 9. The system of any one of Examples 1-9, the operations comprising: receiving an additional request to read data from a memory address of the region; and determining whether data associated with the memory address being read from any of the plurality of planes includes one or more PGBs.

Example 10. The system of Example 9,the operations comprising: in response to determining that the data being read from the plurality of planes excludes the one or more PGBs, applying a same voltage offset to read the data from each of the plurality of planes in parallel.

Example 11. The system of Example 10, wherein the same voltage offset is computed based on a last written page associated with the plurality of planes.

Example 12. The system of any one of Examples 9-11, the operations comprising: in response to determining that the data being read from the plurality of planes includes the one or more PGBs, applying different voltage offsets to read the data from each of the plurality of planes in parallel.

Example 13. The system of Example 12, wherein an individual voltage offset of the different voltage offsets is computed based on a last written page associated with the plurality of planes.

Example 14. The system of Example 13, the operations comprising: determining that the one or more PGBs comprise an individual PGB on the first deck; obtaining information associated with the last written page on the first deck; and computing the individual voltage offset based on the obtained information associated with the last written page on the first deck.

Example 15. The system of any one of Examples 13-14, the operations comprising: determining that the one or more PGBs comprise an individual PGB on the second deck; obtaining information associated with the last written page on the second deck; and computing the individual voltage offset based on the obtained information associated with the last written page on the second deck.

Example 16. The system of any one of Examples 1-15, the operations comprising: storing a table that represents a number of word lines (WLs) that are in an erased state in a first full block (FB) of the first plane used to form the first PGB.

Example 17. The system of Example 16, wherein the first read voltage offset is computed based on the number of WLs that are in the erased state in the first FB of the first plane used to form the first PGB.

Methods and computer-readable storage medium with instructions for performing any one of the above Examples.

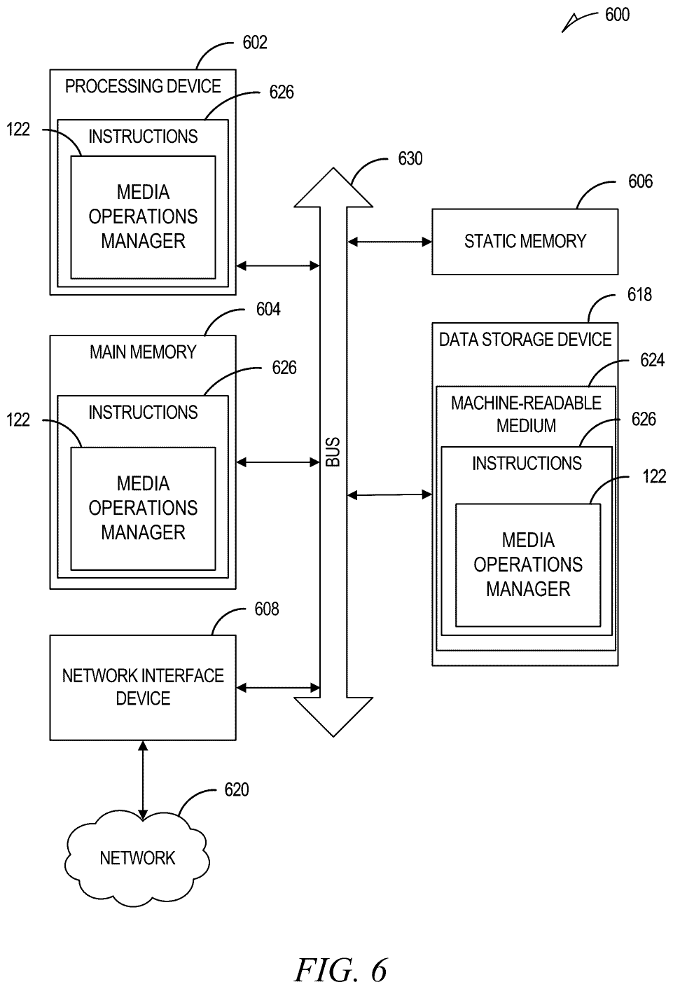

FIG. 6 illustrates an example machine in the form of a computer system 600 within which a set of instructions can be executed for causing the machine to perform any one or more of the methodologies discussed herein. In some examples, the computer system 600 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the media operations manager 122 of FIG. 1). In alternative embodiments, the machine can be connected (e.g., networked) to other machines in a local area network (LAN), an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a network switch, a network bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a data storage system 618, which communicate with each other via a bus 630.

The processing device 602 represents one or more general-purpose processing devices such as a microprocessor, a central processing unit, or the like. More particularly, the processing device 602 can be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processing device 602 can also be one or more special-purpose processing devices such as an application specific integrated circuit (ASIC), a field programmable gate array (FPGA), a digital signal processor (DSP), a network processor, or the like. The processing device 602 is configured to execute instructions 626 for performing the operations and steps discussed herein. The computer system 600 can further include a network interface device 608 to communicate over a network 620.

The data storage system 618 can include a machine-readable storage medium 624 (also known as a computer-readable medium) on which is stored one or more sets of instructions 626 or software embodying any one or more of the methodologies or functions described herein. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage system 618, and/or main memory 604 can correspond to the memory sub-system 110 of FIG. 1.

In one embodiment, the instructions 626 implement functionality corresponding to the media operations manager 122 of FIG. 1. While the machine-readable storage medium 624 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system's memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. Such a computer program can be stored in a computer-readable storage medium, such as, but not limited to, any type of disk including floppy disks, optical disks, CD-ROMs, and magnetic-optical disks; read-only memories (ROMs); random access memories (RAMs); erasable programmable read-only memories (EPROMs); EEPROMs; magnetic or optical cards; or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description above. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine-readable (e.g., computer-readable) storage medium such as a read-only memory (ROM), random access memory (RAM), magnetic disk storage media, optical storage media, flash memory components, and so forth.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system comprising:
a set of memory components of a memory sub-system; and
at least one processing device operatively coupled to the set of memory components, the at least one processing device being configured to perform operations comprising:
identifying a region of the set of memory components, the region comprising a plurality of planes across a plurality of decks of the set of memory components;
generating an individual virtual block (VB) using a first partial good block (PGB) on a first deck of the plurality of decks of the region associated with a first plane of the plurality of planes and a second PGB on a second deck of the plurality of decks associated with the first plane;
receiving a request to read data stored in the region of the set of memory components; and
in response to receiving the request to read the data, applying a first read voltage offset to read the individual VB from the first plane in parallel with applying a second read voltage offset to read an additional VB from a second plane of the plurality of planes.

2. The system of claim 1, wherein the VB is generated using less than all portions of a full block (FB).

3. The system of claim 1, wherein the first PGB includes a first portion categorized as being defective and a second portion categorized as being non-defective.

4. The system of claim 1, wherein the first PGB is formed using less than all portions of a full block categorized as being non-defective.

5. The system of claim 1, wherein the first deck is an upper deck of the region of the set of memory components, and wherein the second deck is a lower deck of the region of the set of memory components.

6. The system of claim 1, the operations comprising:
combining the first PGB and the second PGB to form the virtual block.

7. The system of claim 1, the operations comprising:
storing an independent offset for each plane of the plurality of planes and for each deck of the plurality of decks, the independent offset indicating valid addresses for performing memory operations associated with memory blocks on respective planes of the plurality of planes and respective decks of the plurality of decks.

8. The system of claim 7, wherein the memory operations comprise at least one of programming data to the memory blocks, reading data from the memory blocks, or performing garbage collection operations on data stored in the memory blocks.

9. The system of claim 1, the operations comprising:
receiving an additional request to read data from a memory address of the region; and
determining whether data associated with the memory address being read from any of the plurality of planes includes one or more PGBs.

10. The system of claim 9, the operations comprising:
in response to determining that the data being read from the plurality of planes excludes the one or more PGBs, applying a same voltage offset to read the data from each of the plurality of planes in parallel.

11. The system of claim 10, wherein the same voltage offset is computed based on a last written page associated with the plurality of planes.

12. The system of claim 9, the operations comprising:
in response to determining that the data being read from the plurality of planes includes the one or more PGBs, applying different voltage offsets to read the data from each of the plurality of planes in parallel.

13. The system of claim 12, wherein an individual voltage offset of the different voltage offsets is computed based on a last written page associated with the plurality of planes.

14. The system of claim 13, the operations comprising:
determining that the one or more PGBs comprise an individual PGB on the first deck;
obtaining information associated with the last written page on the first deck; and
computing the individual voltage offset based on the obtained information associated with the last written page on the first deck.

15. The system of claim 13, the operations comprising:
determining that the one or more PGBs comprise an individual PGB on the second deck;
obtaining information associated with the last written page on the second deck; and
computing the individual voltage offset based on the obtained information associated with the last written page on the second deck.

16. The system of claim 1, the operations comprising:
storing a table that represents a number of word lines (WLs) that are in an erased state in a first full block (FB) of the first plane used to form the first PGB.

17. The system of claim 16, wherein the first read voltage offset is computed based on the number of WLs that are in the erased state in the first FB of the first plane used to form the first PGB.

18. A method comprising:
identifying a region of a set of memory components, the region comprising a plurality of planes across a plurality of decks of the set of memory components;
generating an individual virtual block (VB) using a first partial good block (PGB) on a first deck of the plurality of decks of the region associated with a first plane of the plurality of planes and a second PGB on a second deck of the plurality of decks associated with the first plane;
receiving a request to read data stored in the region of the set of memory components; and
in response to receiving the request to read the data, applying a first read voltage offset to read the individual VB from the first plane in parallel with applying a second read voltage offset to read an additional VB from a second plane of the plurality of planes.

19. The method of claim 18, wherein the VB is generated using less than all portions of a full block (FB).

20. A non-transitory computer-readable storage medium comprising instructions that, when executed by at least one processing device, cause the at least one processing device to perform operations comprising:
identifying a region of a set of memory components, the region comprising a plurality of planes across a plurality of decks of the set of memory components;
generating an individual virtual block (VB) using a first partial good block (PGB) on a first deck of the plurality of decks of the region associated with a first plane of the plurality of planes and a second PGB on a second deck of the plurality of decks associated with the first plane;
receiving a request to read data stored in the region of the set of memory components; and
in response to receiving the request to read the data, applying a first read voltage offset to read the individual VB from the first plane in parallel with applying a second read voltage offset to read an additional VB from a second plane of the plurality of planes.
